(19) United States
(12) Patent Application Publication
(10) Pub. No.: US 2012/0040219 A1
(43) Pub. Date: Feb. 16, 2012

(54) SYSTEM FOR FIXING A BATTERY PACK AND ASSOCIATED AUTOMATED METHOD OF ASSEMBLY/DISASSEMBLY

(75) Inventors: Bruno Cappellotti, Magny Les Hameaux (FR); Jacques Tramet, Montigny (FR)

(73) Assignee: RENAULT S.A.S., BOULOGNE-BILLANCOURT (FR)

(21) Appl. No.: 13/122,998

(22) PCT Filed: Sep. 30, 2009
(86) PCT No.: PCT/FR09/51856

§ 371 Date: Nov. 4, 2011

(30) Foreign Application Priority Data
Oct. 7, 2008 (FR) 0856797

(51) Int. Cl. H01M 2/10; H05K 13/00

(52) U.S. Cl. 429/99; 29/592.1

(57) ABSTRACT

The method and system for fixing a battery pack to a receptacle, the battery pack including a housing, with at least one fixing device for the housing to the receptacle, and including a rotating shaft with an alignment shape that can cooperate with a complementary shape on the receptacle, and a cavity for accepting a tool for rotational drive. A cam is driven in rotation by the shaft and includes an extension that can be introduced or removed to or from a housing in the receptacle. The receptacle is provided with a complementary shape and housing opposite each fixing device. A method for automated assembly/disassembly of a battery pack includes such a fixing system.

The present invention relates to a system for attaching a battery pack to a bodyshell such as a bodyshell of a motor vehicle, and to automatable methods for mounting/dismounting such a battery pack.

In the field of the attachment of power batteries to a vehicle, no system/method is known that allows an automatable mounting/dismounting.

The present invention proposes to make the initial placing and the replacement of a power battery automatable, that is to say able to be carried out without manual technical intervention, for example at a service station.

The subject of the invention is a system for attaching a battery pack to a bodyshell, said battery pack comprising a housing, the housing and the bodyshell delimiting between them a space capable of receiving batteries, said housing being furnished with a plurality of at least one device for attaching the housing to the bodyshell on an axis, each device comprising:
a shaft secured to said housing while being free to rotate about the axis relative to said housing, having at one of its ends a centering shape of revolution about the axis capable of interacting with a complementary shape present on the bodyshell, and at its other end a recess capable of receiving a tool for rotation about the axis;
a cam secured to and rotated by the shaft about the axis and having a substantially flat extension in a plane perpendicular to the axis capable, depending on the angle of rotation of said shaft, of being lodged in or dislodged from a casing made in the bodyshell which casing being substantially flat and perpendicular to the axis,
   the bodyshell being furnished with one and the same plurality of complementary shape and of casing facing each attachment device.

According to another advantageous feature, each attachment device also comprises an elastic means placed so as to be compressed, on the axis, between the housing and the bodyshell when the cam is placed in the casing, in order to create, when it is relaxed, a bearing force for forcing the extension of said cam against the wall of said casing.

The invention also relates to an automatable method for mounting a battery pack comprising such an attachment system, comprising the following steps:
placing the housing fitted with batteries on a deck, close to the bodyshell,
moving the deck in order to align each centering shape of the plurality of attachment devices of the housing with a corresponding complementary shape of the bodyshell,
moving the deck along the axis in order to insert each centering shape of the plurality of attachment devices of the housing into the corresponding complementary shape of the bodyshell,
rotating each shaft by means of a tool engaged in each recess so as to place each cam of the plurality in each corresponding casing,
removing the deck.

The invention also relates to an automatable method for dismounting a battery pack comprising such an attachment system, comprising the following steps:
placing a deck in contact with the housing,
rotating each shaft by means of a tool engaged in each recess so as to dislodge each cam of the plurality from each corresponding casing,
moving the deck along the axis in order to extract each centering shape of the plurality of attachment devices of the housing from the corresponding complementary shape of the bodyshell,
removing the deck taking away the battery pack.

According to another feature of the invention, the mounting and dismounting methods also comprise a movement of the deck along the axis, compressing, if necessary, each elastic means, and the removal of the deck is carried out by relaxing, if necessary, each elastic means.

One advantage of the device according to the invention is that it allows automation of the placement and replacement of a power battery pack.

Another advantage of the system is that it is based on simple mechanical elements providing good robustness and an ease of industrial application.

Other features, details and advantages of the invention will emerge more clearly from the detailed description given below as an indication with respect to the drawings in which:

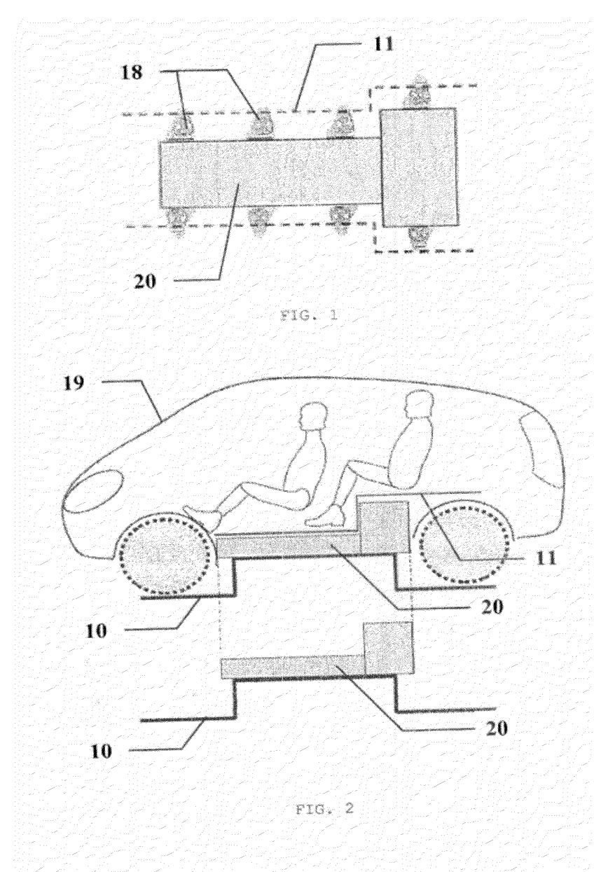

FIG. 1 shows an example of a battery pack in a view from above,

FIG. 2 shows this same battery pack in a view from the side, and its placement on the vehicle,

FIG. 3 shows an attachment device according to the invention in a perspective view,

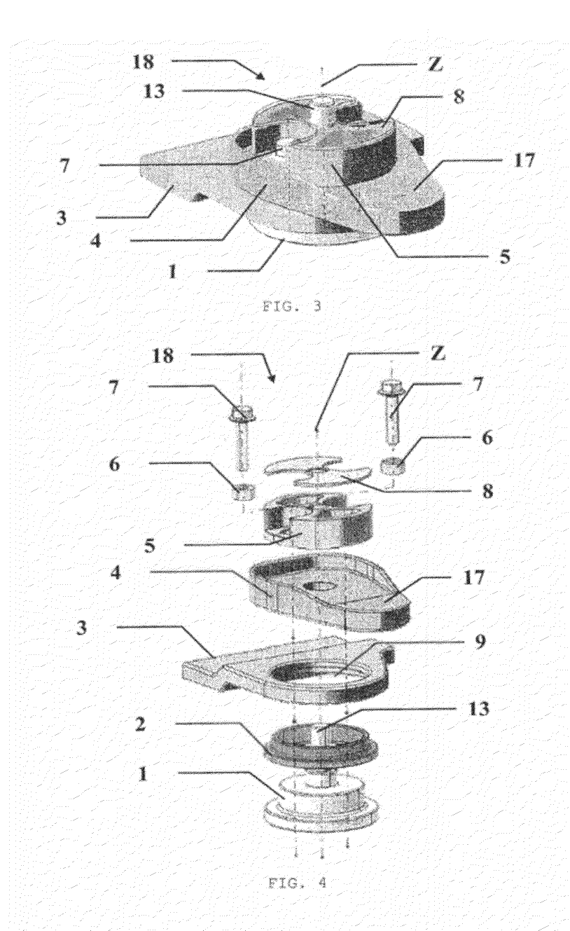

FIG. 4 shows the same device in an exploded view,

FIG. 5 illustrates, on a device seen from above, two planes of section 1 and 2,

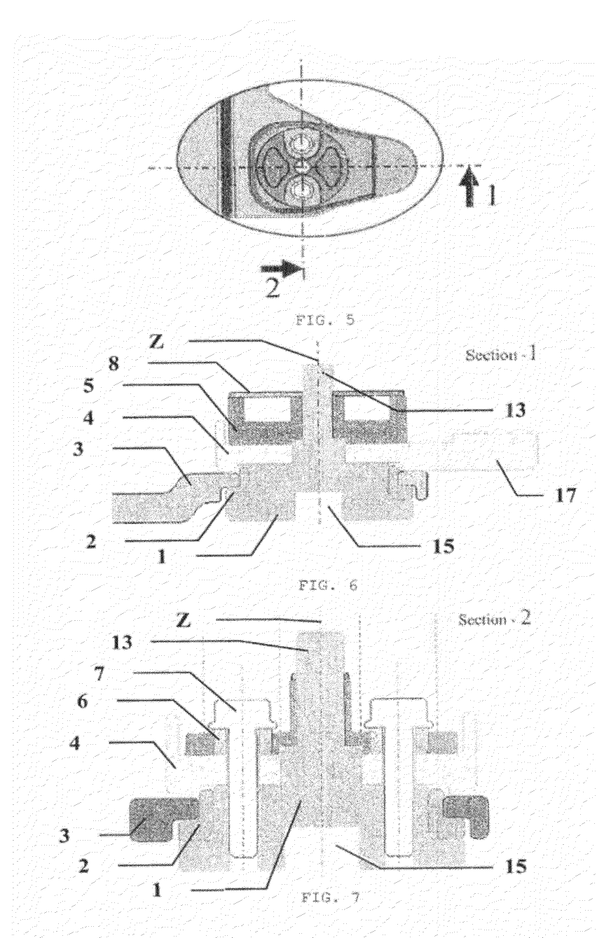

FIG. 6, respectively 7, shows the attachment device according to the invention in a sectional view along the sectional plane 1, respectively along the sectional plane 2,

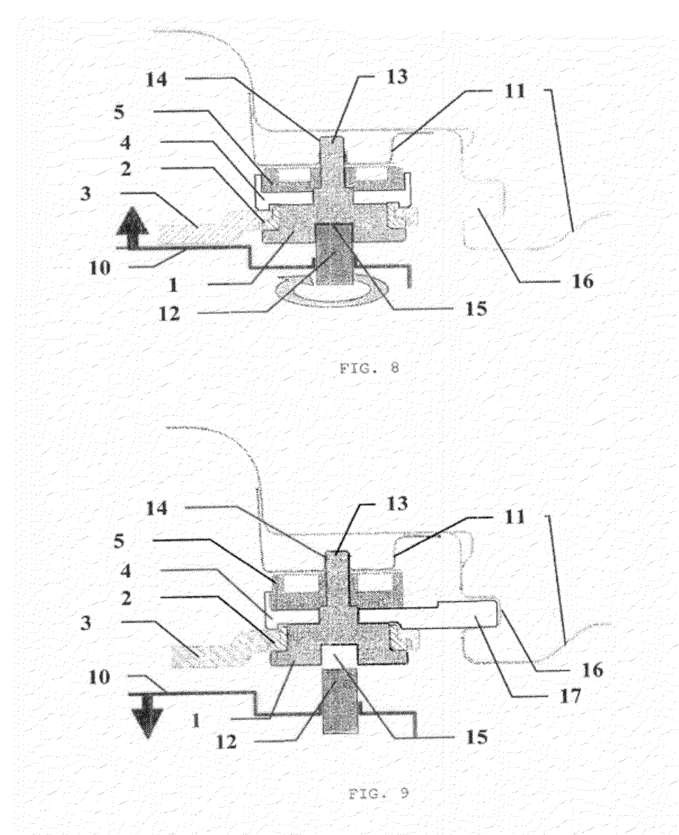

FIGS. 8 and 9 illustrate two steps in the placement of the attachment device on the bodyshell.

According to FIG. 1, a battery pack 20 has a shape that can be complex. According to the invention it is fitted with a plurality of at least one attachment device 18, in this instance eight in number and distributed on its periphery, in order to allow the battery pack 20 to be attached to the bodyshell 11.

FIG. 2 illustrates an example of placement of said battery pack 20, in an illustrative manner, beneath the vehicle 19. Such a placement is advantageously carried out by means of a movable deck 10.

With reference to FIGS. 3 and 4 showing a preferred embodiment of an attachment device 18, respectively shown in a perspective view (FIG. 3) and in an exploded view (FIG. 4), and to FIGS. 6 and 7 showing two perpendicular sections of the same embodiment, a housing 3 secured to the battery pack 20 is partially illustrated. Said housing 3 is pierced with a circular hole 9. Into this hole 9 is placed, if necessary, by means of a centering ring 2, a circular shaft 1 with an axis of revolution Z. Thus said shaft 1 is free to rotate about the axis Z. Said shaft 1 can have a shoulder, as illustrated, in order to butt against the housing 3. The shaft 1 has at one of its ends a centering shape 13 of revolution about the axis Z. This centering shape 13 is capable of interacting with a complementary shape 14 made on the bodyshell 11.

In the example illustrated, the centering shape 13 is a cylindrical protrusion, while the complementary shape 14 is a cylindrical recess, of slightly greater diameter, in order to be able to receive the centering shape 13 moving in translation along the axis Z. It appears that the shape 13, respectively 14, could be any other shape of revolution (for example a cone), the centering shape 13 being able to be a recess or the complementary shape being able to be protrusion, as long as the two shapes 13, 14 remain complementary with one another. At its other end, the shaft 1 comprises a recess 15 capable of receiving a tool 12 for rotating about the axis Z. This recess is more evident in FIGS. 6-9.

Also placed on the shaft 1, on the side opposite to the shoulder relative to the housing 3, is a cam 4. This cam 4 is secured in rotation to the shaft 1. This securing can be obtained by means of a complementary prismatic profile of the shaft 1 and of the cam 4 at their interface (solution not shown). This securing can also be obtained by means of an attachment of the cam 4 to the shaft 1 achieved, as in the example illustrated, by two screws 7. Said attachment, in that it traps the housing 3 between the cam 4 and the shaft 1, secures the attachment device 18 to the housing 3.

The cam 4 is substantially flat on a plane perpendicular to the axis Z and substantially circular in this same plane, except for an extension 17 extending mainly in a radial direction.

With reference now to FIGS. 8 and 9, the operating method of said attachment device 18 will now be described in detail. The extension 17 is such that it is capable, depending on the angle of rotation of the cam 4 and of said shaft 1, of being lodged in or dislodged from a casing 16 made in the bodyshell 11, which casing being substantially flat, perpendicular to the axis Z and placed facing the cam 4, when the centering shape 13 of the shaft 1 of the attachment device 18 is engaged in the complementary shape 14.

FIGS. 8 and 9 show an attachment device 18 seen from the side and in sectional view, with respect to a detail of the bodyshell 11 comprising a complementary shape 14 capable of receiving the centering shape 13 of the shaft 1 and a casing 16. In FIG. 8, the cam 5 is oriented such that the extension 17 is dislodged from the casing 16: the attachment device is then unlocked. On the other hand, in FIG. 9, the cam 5 is oriented such that the extension 17 is lodged in the casing 16: the attachment device is then locked.

According to a preferred embodiment, the attachment device 18 also comprises an elastic means 5, in this instance an elastomer part. This means 5 is placed so as to be compressed, on the axis Z, between the housing 3 and the bodyshell 11 when the cam 4 is placed in the casing 16, in order to create, when the elastic means 5 is relaxed, a bearing force for forcing the extension 17 of said cam 4 against the wall of said casing 16. Therefore, as illustrated in FIG. 8, the device 18 is moved, by a pressure along the axis Z, upward in the plane of the figure, so as, on the one hand, to compress the elastic means 5 and, on the other hand, to allow the cam 4 to be placed facing the casing 16 in order to allow a rotation that will allow it to be put in place. When this rotation has been carried out, as illustrated in FIG. 9, said pressure can be relaxed, causing a partial relaxation of the elastic means 5. The extension 17 of the cam 4 comes into contact along the axis Z with one face of the casing 16. The residual compression of the elastic means 5 then produces a pressure of the extension 17 of said cam 4 against the wall of said casing 16. The attachment device 18 is held in position, relative to the bodyshell 11, under the combined action of the centering of the centering shape 13 with respect to the complementary shape 14, and of the contact of the cam 4 in the casing 16. The additional pressure due to the elastic means 5 reinforces this positional hold and makes the attachment better able to withstand the impacts and vibrations that can occur on a vehicle 19.

The elastomer part 5 is assembled with the shaft 1 by means of screws 7. The two inserted spacers 6 have a height substantially equal to the thickness of the part at the same level as the attachment, so that tightening the screws 7 does not deform said part 5.

A plate 8 is advantageously placed on top of the elastomer part 5 in order to protect it and to spread the compression. It is assembled on the part 5 by any known means, for example by bonding or vulcanization.

According to an advantageous arrangement, the battery pack 20 and the housing 3 are placed underneath the bodyshell 11. Thus the battery pack 20 is protected and mounting/dismounting from beneath the vehicle is possible, for example by means of a hoist or from a pit.

In order to be able to place the centering of the centering shapes 13 relative to the complementary shapes 11, the axes Z of the attachment devices 18 of the plurality are advantageously parallel.

In order to combine the advantages of access from beneath and moreover a use of gravity for the placing/replacing of a battery pack 20, the battery pack 20 then being simply placed on the housing 3, the axis Z of the attachment devices 18 is advantageously vertical.

The attachment system 18 as described above advantageously makes it possible to develop an automatic mounting and/or dismounting method with no manual intervention.

Mounting comprises the following steps in succession. The battery pack 20 consisting of the housing 3 furnished with batteries is placed on a deck 10 close to the bodyshell 11, preferably close to the zone for placement on the vehicle 19. The deck 10 can be moved and is moved in order to align the axis of each centering shape 13 of an attachment device 18 with the axis of the corresponding complementary shape 14 made in the bodyshell 11. The deck 10 is then moved parallel to itself, in order to move closer to the bodyshell 11, by a translational movement along the axis Z. This inserts said centering shapes 13 into said complementary shapes 14 of the bodyshell 11. In the event of an embodiment with an elastic means 5, the latter is compressed during this movement. While thus holding the battery pack 20, the shaft 1 of each attachment device 18 is turned, for example by means of a tool 12 engaged in the recess 15, in order to engage the extension 17 of the cam 4 in the corresponding casing 16 of the bodyshell 11. Only one tool 12 can sequentially rotate all of the cams 4. Alternatively, up to one tool 12 per device 18 can be used. The battery pack 20 is at this stage attached to the bodyshell 11, and the deck 10 can be removed. If an elastic means 5 is used, the removal of the deck causes a partial relaxation of said elastic means 5 which allows a partial compression of the elastic means 5 to remain, which causes pressure from the cam 4 in the casing 16 and therefore reinforces the attachment.

Dismounting comprises steps that are substantially the reverse of the mounting. It comprises the following steps in succession. The deck 10 is placed in contact with the housing 3 of the battery pack 20. If an elastic means 5 is used, an additional step moves the deck 10, along the axis Z, closer to the bodyshell 11 in order to compress the elastic means 5 and to align the cams 4 with the casings 16, in order to remove the pressure previously described so as to make disengagement of the cams 4 easier. The shafts 1 of the attachment devices 18 are then turned, for example by means of one or more tools 12 each engaged in a recess 15, in order to turn the cams 4 so as to dislodge the extension 17 from the corresponding casing 16. The deck is then moved along the axis Z, away from the bodyshell 11, in order to extract the centering shapes 13 from the corresponding complementary shapes 14 of the bodyshell 11. The battery pack 20 is then detached from the bodyshell and removing the deck 10 allows it to be set down.

It is apparent to those skilled in the art that the mounting/dismounting steps can be carried out manually but also advantageously in a totally automated manner.

1-9. (canceled)

10. A system for attaching a battery pack to a bodyshell,
the battery pack comprising a housing, the housing and the bodyshell delimiting between them a space capable of receiving batteries, wherein the housing includes a plurality of at least one device for attaching the housing to the bodyshell on an axis, each attachment device comprising:
a shaft secured to the housing while being free to rotate about the axis relative to the housing, having at one of its ends a centering shape of revolution about the axis capable of interacting with a complementary shape present on the bodyshell, and at its other end a recess capable of receiving a tool for rotation about the axis;
a cam secured to and rotated by the shaft about the axis and having a substantially flat extension in a plane perpendicular to the axis capable, depending on an angle of rotation of the shaft, of being lodged in or dislodged from a casing made in the bodyshell, which casing is substantially flat and perpendicular to the axis, and
wherein the bodyshell includes one and the same plurality of complementary shape and of casing facing each attachment device.

11. The system as claimed in claim 10, wherein each attachment device further comprises an elastic means placed so as to be compressed, on the axis, between the housing and the bodyshell when the cam is placed in the casing, to create, when it is relaxed, a bearing force for forcing the extension of the cam against the wall of the casing.

12. The system as claimed in claim 10, wherein the housing is placed underneath the bodyshell.

13. The system as claimed in claim 10, wherein the axes of the plurality of attachment devices are parallel.

14. The system as claimed in claim 10, wherein the axis of the attachment devices is vertical.

15. An automatable method for mounting a battery pack including an attachment system as claimed in claim 10, the method comprising:
placing the housing fitted with batteries on a deck, close to the bodyshell;
moving the deck to align each centering shape of the plurality of attachment devices of the housing with a corresponding complementary shape of the bodyshell;
moving the deck along the axis to insert each centering shape of the plurality of attachment devices of the housing into the corresponding complementary shape of the bodyshell;
rotating each shaft by a tool engaged in each recess so as to place each cam of the plurality in each corresponding casing; and
removing the deck.

16. The method as claimed in claim 15, wherein the moving the deck along the axis is carried out by compressing, if necessary, each elastic means and the removing the deck is carried out by relaxing, if necessary, each elastic means.

17. An automatable method for dismounting a battery pack comprising an attachment system according to claim 10, the method comprising:
placing a deck in contact with the housing;
rotating each shaft by a tool engaged in each recess so as to dislodge each cam of the plurality from each corresponding casing;
moving the deck along the axis to extract each centering shape of the plurality of attachment devices of the housing from the corresponding complementary shape of the bodyshell; and
removing the deck taking away the battery pack.

18. The method as claimed in claim 17, wherein the rotating is preceded by a movement of the deck along the axis, compressing, if necessary, each elastic means, and the removing the deck is carried out by relaxing, if necessary, each elastic means.
